(19) United States
(12) Patent Application Publication
(10) Pub. No.: US 2002/0127763 A1
(43) Pub. Date: Sep. 12, 2002

(54) Sidewall spacers and methods of making same

(76) Inventors: Mohamed Arafa, Chandler, AR (US); Weimin Han, Portland, OR (US); Alan M. Myers, Portland, OR (US); Daniel A. Simon, Hillsboro, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 09/752,798

(22) Filed: Dec. 28, 2000

(51) Int. Cl. H01L 21/00

(52) U.S. Cl. 438/76

(57) ABSTRACT

L-shaped spacers for use adjacent to the vertical sidewalls of gate electrodes in the manufacture of MOS integrated circuits are described along with methods of fabricating such structures that do not require any additional cost compared to conventional manufacturing processes. A spacer is formed as a tri-layer of silicon oxide/silicon nitride/silicon oxide deposited in- situ at low temperature using a conventional furnace and a bis(tertiarybutylamino) silane chemistry deposition. The spacer has the same performance as a conventional spacer during deep source/drain (S/D) implants. Prior to a cleaning operation which precedes silicidation, the top oxide layer is removed leading to improved gap-fill characteristics. The upper oxide may to removed before deep S/D implantation to further achieve reduction of series resistance.

### BACKGROUND OF THE INVENTION

1. Field of the Invention

The present invention relates generally to the field of integrated circuit manufacturing, and more specifically, to the formation of field effect transistors (FETs) and sidewall spacers adjacent to such FETs.

2. Background

Advances in semiconductor manufacturing technology have led to the integration of tens, and more recently hundreds, of millions of circuit elements, such as transistors, on a single integrated circuit (IC). To achieve such dramatic increases in the density of circuit components has required semiconductor manufacturers to scale down the size of the circuit elements and the interconnection structures used to connect the circuit elements into functional circuitry, as well as scaling down the spacing between the interconnect.

One consequence of reducing the spacing between circuit elements has been the increased difficulty of filling the gaps between adjacent, or neighboring, FET gate electrodes with dielectric material. Modern FETs, that is those with deep submicron channel lengths, are typically formed such that sidewall spacers exist along opposing sides of the gate electrodes. Prior to formation of these sidewall spacers, a first ion implant operation is performed so as to form the doped tip regions (also sometimes referred to as source/drain extensions). After the sidewall spacers are formed, a deep source/drain implant is performed wherein the sidewall spacers have the desirable attribute of blocking the deep source/drain implant. By effectively moving the deep source/drain implant away from the channel region of the FET, various undesirable short-channel effects are avoided.

Unfortunately, the addition of sidewall spacers decreases the spacing between the adjacent, or neighboring, FET gate electrodes. When a dielectric material such as phosphorous doped glass is used to fill these narrow gaps, the formation of voids has been observed in those gap regions.

FIG. 1 illustrates a substrate 102 and a pair of FETs 104a, 104b, each including a gate electrode 106 disposed over a gate dielectric layer 107, and further including source/drain regions 112. FETs 104a, 104b also have conventional sidewall spacers. The spacers include a first layer 106 and a second layer 108 as shown. When a dielectric layer 114 of phosphorous doped glass is formed over substrate 102 and FETs 104a, 104b, a void 116 develops as a result of the narrow spacing between FETs 104a, 104b.

While voids can actually provide the electrical benefit of reducing parasitic capacitance between electrical nodes, these same voids introduce manufacturing problems when contacts need to be formed between a junction, or source/drain (S/D) region, and an overlying metal layer. In particular, when a void occurs at a location, at or adjacent to, where a contact is to formed, the void and the contact hole may combine to form a cavity in which a contact may not be able to be formed, or in which other reliability problems may occur. For example, in some processes for manufacturing integrated circuits, an adhesion layer is deposited onto the surfaces of the contact hole. However it may not be possible to successfully perform this operation when the intended shape of the contact hole is distorted by its intersection with a void.

Another undesirable consequence of the interaction of contact holes and voids is the possibility of electrically shorting two or more contacts. In the case where a void exists between the location of two contact holes, and the void spans, or substantially spans, the distance between those contact holes, then a breach may be formed. That is, when the contact holes are filled it is possible for them to be electrically shorted by conductive material moving through the breach created from the void.

Accordingly, there is a need for methods and structures to prevent the formation of voids in the interlayer dielectric material when the spacing of structures such as gate electrodes is very small.

### BRIEF DESCRIPTION OF THE DRAWINGS

FIG. 1 is a schematic cross-sectional view of a pair of prior art FETs formed with conventional sidewall spacers.

FIG. 2 is a schematic cross-sectional view of a pair of FETs with sidewall spacers in accordance with the present invention.

FIG. 3 is a schematic cross-sectional view of a pair of gate electrodes disposed over gate dielectrics, which in turn, are disposed over a substrate.

FIG. 4 is a schematic cross-sectional view of the structure of FIG. 3, after conformal deposition of a first oxide layer, a nitride layer, and a second oxide layer.

FIG. 5 is a schematic cross-sectional view of the structure of FIG. 4, after the second oxide layer, the silicon nitride layer, and the first oxide layer have been anisotropically etched such that they are removed from the top surface of the gate electrodes but a portion of each layer remains adjacent the vertical sidewalls of the gate electrode.

FIG. 6 is a schematic cross-sectional view of the structure of FIG. 5, after the deep source/drain implants have been made.

FIG. 7 is a schematic cross-sectional view of the structure of FIG. 6, after the remaining portion of the second oxide layer is removed.

FIG. 8 is a schematic cross-sectional view of the structure of FIG. 5, after the remaining portion of the second oxide layer is removed.

FIG. 9 is a schematic cross-sectional view of the structure of FIG. 8, after the deep source/drain implants have been made.

FIG. 10 is a flow diagram showing the operations of forming sidewall spacers in accordance with the present invention.

FIG. 11 is a flow diagram showing the operations of forming FETs in accordance with the present invention.

FIG. 12 is a flow diagram showing alternative operations for forming FETs in accordance with the present invention.

### DETAILED DESCRIPTION

Structures and methods useful in the manufacture of integrated circuits are described. In the following description numerous specific details are set forth to provide an understanding of the present invention. It will be apparent, however, to those skilled in the art and having the benefit of this disclosure, that the present invention may be practiced with apparatus and processes that vary from those specified herein.

Reference herein to “one embodiment”, “an embodiment”, or similar formulations, means that a particular feature, structure, or characteristic described in connection with the embodiment is included in at least one embodiment of the present invention. Thus, the appearances of such phrases or formulations herein are not necessarily all referring to the same embodiment. Furthermore, various particular features, structures, or characteristics may be combined in any suitable manner in one or more embodiments.

Terminology

The terms, chip, integrated circuit, monolithic device, semiconductor device or component, microelectronic device or component, and similar terms and expressions, are often used interchangeably in this field. The present invention is applicable to all the above as they are generally understood in the field.

The terms contact and via, both refer to structures for electrical connection of conductors from different interconnect levels. These terms are sometimes used in the art to describe both an opening in an insulator in which the structure will be completed, and the completed structure itself. For purposes of this disclosure contact and via refer to the completed structure.

A substrate may also be referred to as a wafer. Wafers, may be made of semiconducting, non-semiconducting, or combinations of semiconducting and non-semiconducting materials. Silicon wafers may have thin films of various materials formed upon them.

The term vertical, as used herein, means substantially perpendicular to the surface of a substrate.

Conventional sidewall spacers have been formed of one or more layers of material. One previous approach to forming a multi-layer sidewall spacer involved depositing, over the patterned gate electrodes, a thin layer, e.g., 100 to 150 angstroms, of silicon oxide from the thermal decomposition of tetraethylorthosilicate (TEOS), followed by depositing between 500 and 800 angstroms of silicon nitride from a low temperature decomposition of bis(tertiarybutylamino) silane, and then selectively etching the nitride layer with a dry etch operation and using detection of the underlying oxide layer to determine the etch end point. Wet cleaning operations were typically used to remove the remaining oxide. Such a process leaves a two-layer oxide/nitride spacer adjacent opposing vertical sidewalls of the gate electrodes.

The gap-fill requirements, for providing a substantially void-free interlayer dielectric layer, are known to become more stringent and difficult to achieve when the minimum spacing between adjacent gate electrodes decreases. Since the gate electrodes have sidewall spacers adjacent thereto, the measure of the gap is actually the distance between the adjacent sidewall spacers. The gap-fill requirements can impose various constraints, such as, for example, a reduced thickness for the spacer which may limit transistor performance optimization; and/or a reduced nitride etch stop layer thickness which may require the development of a more selective contact etch to allow unlanded contacts.

Embodiments of the present invention provide a method of forming a sidewall spacer by in-situ deposition of a tri-layer of silicon oxide/silicon nitride/silicon oxide using bis-(tertiarybutylamino) silane (BTBAS) as one of the source gases for the formation of all three layers. A double end-point detection scheme can be used to etch the upper oxide and stop on the nitride and then etch the nitride and stop on the bottom oxide. Spacers formed in this way may look and behave like conventional spacers during the deep source/drain (S/D) implant. The upper oxide portion of the spacer is subsequently removed during wet clean operations performed prior to the silicide formation operations. The removal of the upper oxide portion of the spacer facilitates achievement of the gap-fill requirements for the interlayer dielectric film, which is formed over the FETs, by effectively increasing the lateral space between the sidewall spacers of adjacent transistors. This interlayer dielectric film is sometimes referred to in the literature as ILD0.

If the upper oxide portions of the spacer are removed before the deep S/D implant operation is performed, then the nitride and lower oxide layer thicknesses can be selected to provide partial penetration by the deep S/D implants. The additional dopants that reach the S/D region in this way provide an improved doping profile between the tip region and the deep SID, which results in the series resistance from the tip into the S/D being reduced. This partial penetration implant may be performed on both P and N type transistors in CMOS integrated circuits, or alternatively, on just one type by removing the upper oxide for only one type of FET prior to its deep S/D implant.

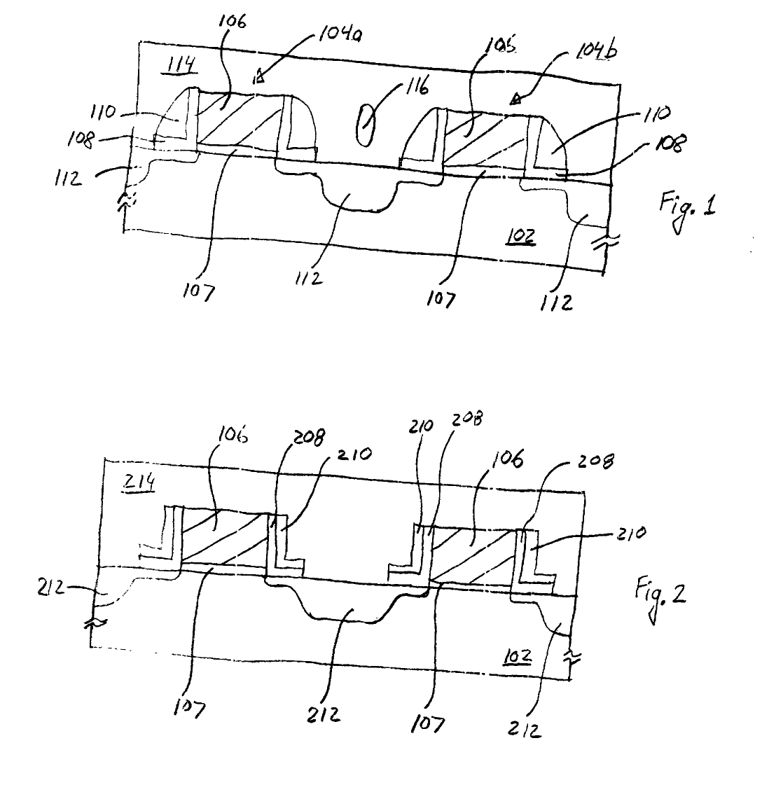

FIGS. 2-9 are various schematic cross-sectional views illustrating the structural outcomes of various processing operations. Two alternative process flows and resulting structures in accordance with the present invention are shown.

FIG. 2 shows a portion of a partially processed wafer embodying two FETs in accordance with the present invention, and a void-free interlayer dielectric disposed over and between those FETs. More particularly, a substrate 102, typically a silicon wafer, has gate a pair of gate dielectric layers 107 disposed thereon, with a pair of gate electrodes 106, disposed respectively on the pair of gate dielectric layers 107. Each gate electrode 106 has sidewall spacers disposed adjacent thereto. As shown in FIG. 2, these spacers include an oxide layer 208 immediately adjacent to gate electrodes 106 and a nitride layer 210 disposed on the oxide layer. Together, oxide layer 208 and nitride layer 210, comprise an L-shaped spacer. The L-shaped spacers increase the effective size of the gap between the FETs thereby reducing the incidence of voids in an interlayer dielectric 214. Also shown in FIG. 2, are source/drain regions 212. S/D regions 212 have a doping profile that is more gradual between the thin tip region, which is closest to the channel region of the FET, and the deep S/D region, than the doping profile seen in the conventional structure of FIG. 1.

An illustrative embodiment of the present invention includes the in-situ formation of a tri-layer oxide/nitride/oxide sidewall spacer, and uses bis(tertiarybutylamino) silane as a source gas for the deposition of each of the three layers.

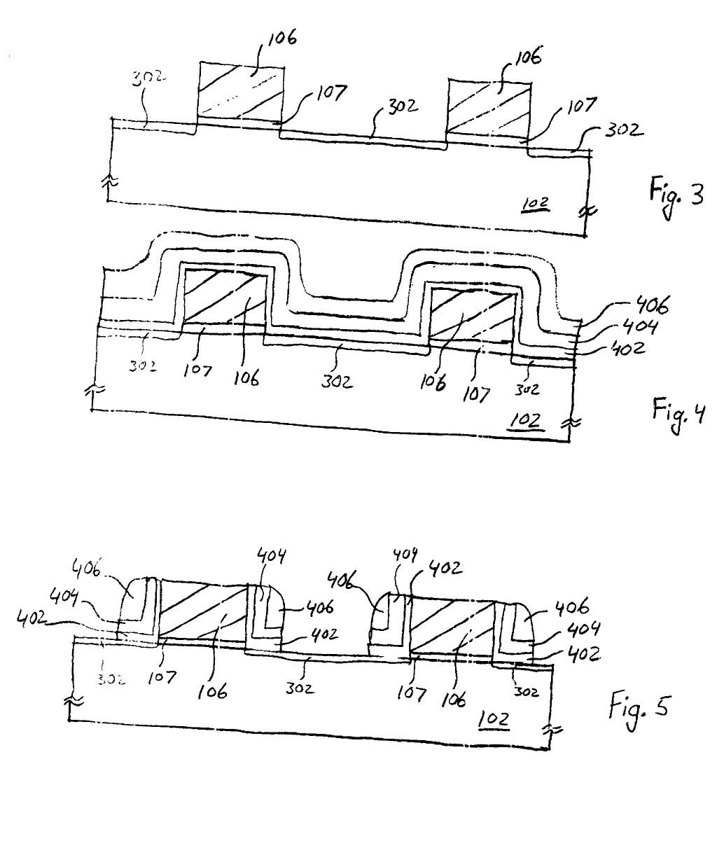

FIG. 3 shows a portion of a partially processed wafer having gate electrodes 106 disposed over gate dielectric layers 107, with gate dielectric layers 107 disposed, in turn, on the surface of a substrate 102. Tip regions (sometimes referred to as source/drain extensions) 302 are disposed in substrate 102 in alignment with gate electrodes 106. This skilled in this field will recognize that these tip regions are generally formed by ion implantation, and that the material implanted is of a conductivity type opposite the conductivity type of substrate 102. Gate electrodes 106, gate dielectrics 107, and tip regions 302, may be formed by conventional well-known methods.

FIG. 4 shows the structure of FIG. 3, after the processing operations of forming a first silicon oxide layer 402, a silicon nitride layer 404, and a second silicon oxide layer 406. Layers 402, 404, and 406 are formed in a furnace without being removed between the formation of the individual layers. Furthermore, each of layers 402, 404, and 406 are formed from a combination of sources that includes, for each layer, bis(tertiarybutylamino) silane.

FIG. 5 shows the structure of FIG. 4, after the processing operations of anisotropically etching first silicon oxide layer 402, silicon nitride layer 404, and second silicon oxide layer 406. This produces tri-layer sidewall spacers that are, in terms of shape, equivalent to conventional sidewall spacers.

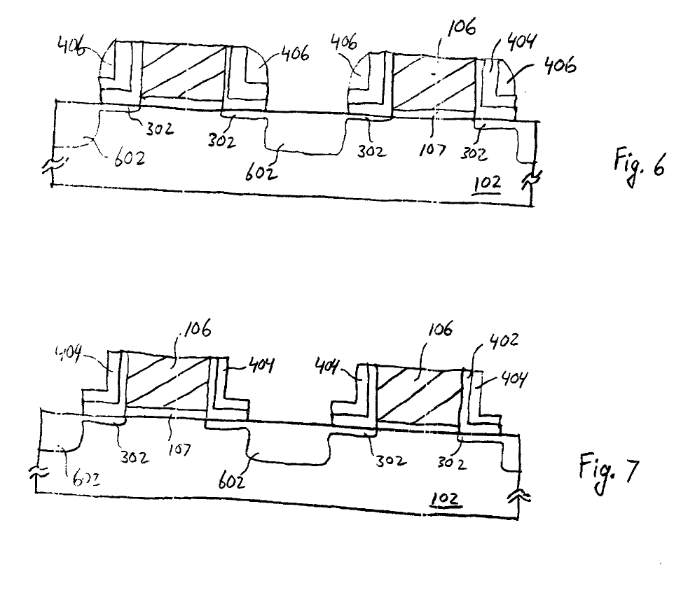

FIG. 6 shows the structure of FIG. 5, after the processing operation of performing a deep S/D implant. The deep S/D implant produces the doped region 602. The transition of the doping profile between tip region 302 and deep S/D 602 is sharp. This profile occurs because the sidewall spacers that include second oxide layer 406, as shown in FIG. 6, block the deep SID implant from reaching that part of substrate 102 that underlies the sidewall spacers.

FIG. 7 shows the structure of FIG. 6, after the processing operations of removing second oxide layer 406 from the sidewall spacers, thus creating L- shaped spacers. As noted above, the L-shaped spacers provide a larger gap thereby making it easier to produce a void-free dielectric layer, as is shown in FIG. 2.

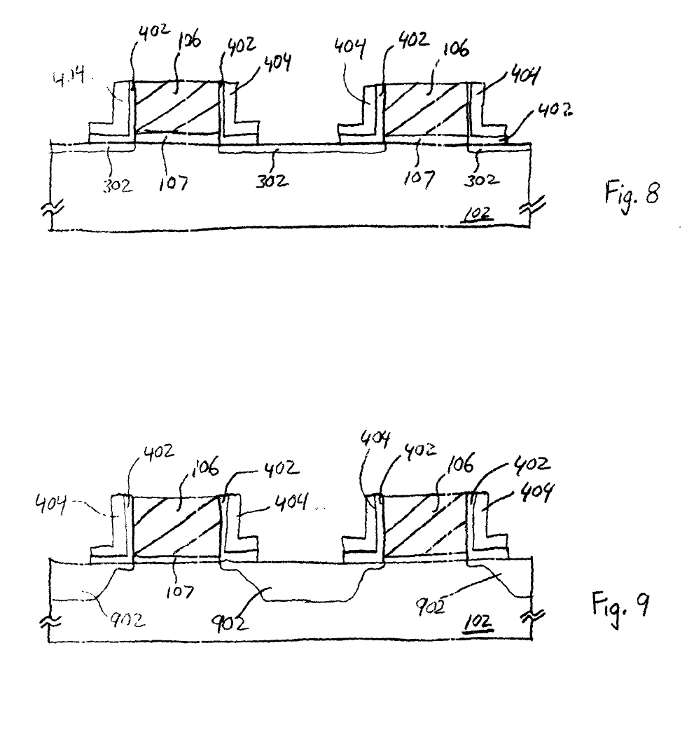

FIGS. 8-9 illustrate an alternative process flow in accordance with the present invention. More particularly, FIG. 8 shows the structure of FIG. 5, after the processing operations that remove second oxide layer 406 from the sidewall spacers, thus creating L-shaped spacers that consist of first silicon oxide layer 402 and silicon nitride layer 404. FIG. 9 shows the structure of FIG. 8, after the processing operation of performing a deep S/D implant. The deep SID implant produces a doped region 902. The transition of the doping profile between tip region 302 and deep S/D 902 is gradual relative to that shown in FIGS. 6-7. This profile occurs because the L-shaped sidewall spacers that have had second oxide layer 406 removed, as shown in FIG. 8, allow the deep S/D implant to reach that part of substrate 102 that underlies the sidewall spacers In one embodiment of the present invention, the formation of the tri-layer of oxide/nitride/oxide from bis(tertiarybutylamino) silane is done in a vertically oriented furnace. In this exemplary embodiment, summarized in Table 1, the furnace is initially at idle at 350° C. with a 5.0 liters/minute N₂ purge at atmospheric pressure. Wafers are then loaded into a boat and the boat moved up into the furnace at a speed of 500 mm/minute. The temperature in the furnace is then set to the range used for the first oxide deposition operation, that is 550° C. to 580° C. The gas flow (N₂ purge) is stopped and the pressure in the furnace is then reduced to about 10 mTorr. After the temperature is stable, the first oxide deposition process is begun with a gas flow of 0.2 liter/minute of O₂ being passed through the furnace at 15 Pa for 5 minutes. Then, still at 15 Pa, the gas mixture is changed to 0.2 liters/minute of O₂ and 0.55 liters/minute of bis(tertiarybutylamino) silane for 6 minutes and 40 seconds.

At a pressure of 10 mTorr, a post-oxide-deposition purge with nitrogen at 0.3 liters/minute for 5 minutes is performed. While maintaining a nitrogen gas flow rate of 0.3 liters/minute, and setting the pressure to 65 Pa, the temperature in the furnace is set to the temperature for the nitride deposition, which is 580° C. to 600° C. While maintaining the temperature range and pressure in the furnace, a flow of ammonia gas (NH₃) through the furnace at 0.4 liters/minute is established for a period of 5.0 minutes. Again while maintaining the same temperature range and pressure in the furnace, and while maintaining the flow of NH₃, a flow of bis(tertiarybutylamino) silane at 0.55 liters/minute is established. This combined flow of ammonia and bis(tertiarybutylamino) silane is continued for 49 minutes. After this 49 minute period, the ammonia and bis(tertiarybutylamino) silane flows are discontinued.

A post-nitride-deposition purge operation is then performed. The post-nitride-deposition purge operation is accomplished by flowing nitrogen at 0.5 liters/minute through the furnace at the same temperature range and a pressure of 10 mTorr for 10 minutes.

Reaction conditions are then set for the second oxide deposition. More particularly, the furnace temperature is set to a range of 550° C. to 580° C. while maintaining the same gas flow and pressure for 5 seconds. While maintaining the furnace temperature is set to a range of 550° C. to 580° C., a gas flow of 0.2 liters/min of O₂ is established and continued at a pressure of 15 Pa for 5 minutes. Finally, while continuing the above, a gas flow of 0.55 ml/min of BTBAS is established and continued for 39 minutes.

A post-oxide-deposition purge is performed at the same temperature but setting the gas flow to 0.3 liters/minute of N₂ at 10 mTorr for five minutes. The temperature can then be ramped down to 350° C. while flowing 0.5 liters/minute of N₂ at 10 mTorr for five minutes. Venting is performed at 350° C. while flowing 5.0 liters/minute of N₂ at atmospheric pressure for 25 minutes. The boat is lowered down at a speed of 60 mm/minute for 20 minutes while maintaining 350° C. and flowing 5.0 liters/minute of N₂ at atmospheric pressure. Wafers are cooled while flowing nitrogen and unloaded. If there are no additional wafers to process the furnace is put in its idle state.

TABLE 1

| Operation | Temperature | Gas Flow | Pressure | Time | |
|---|---|---|---|---|---|
| Furnace Idle | 350° C. | 5.0 l/min N₂ purge | Atmospheric | | |
| Wafer loading | same | same | same | 20 | min |
| Wafer boat up | same | same | same | 3 | min |
| | | | | (speed = 500 mm/min) | |
| Temp set 1^{st} oxide | 550-580° C. | same | same | 5 | sec |
| Pump Down | same | NONE | 10 mTorr | 35 | min |
| Temp stable | same | none | 10 mTorr | 30 | min |
| Pre OX dep | same | 0.2 l/min O₂ | 15 Pa | 5 | min |
| 1st OX dep | same | 0.2 l/min O₂ | | | |
| | | 0.55 ml/min BTBAS | 10 mTorr | 6:40 | min |
| post dep purge | same | 0.3 l/min N₂ | 10 mTorr | 5 | min |
| Nit temp set | 580-600° C. | same | 65 Pa | 5 | sec |
| Pre Ni dep | same | 0.4 l/min NH₃ | same | 5 | min |
| Nit dep | same | 0.4 l/min NH₃ | | | |
| | | 0.55 ml/min BTBAS | same | 49 | min |
| post dep purge | same | 0.5 l/min N₂ | 10 mTorr | 10 | min |
| Ox temp set | 550-580° C. | same | 10 mTorr | 5 | sec |
| Pre OX dep | same | 0.2 l/min O₂ | 15 Pa | 5 | min |
| 2nd OX dep | same | 0.2 l/min O₂ | | | |
| | | 0.55 ml/min BTBAS | same | 39 | min |
| post dep purge | same | 0.3 l/min N₂ | 10 mTorr | 5 | min |
| Temp down | 350° C. | 0.5 l/min N₂ | 10 mTorr | 5 | min |
| Vent | 350° C. | 5.0 l/min N₂ | atmospheric | 25 | min |
| Boat down | same | same | same | 20 | min |
| | | | | (Speed = 60 mm/min) | |
| Wafer cool | same | same | same | 10 | min |
| Wafer unload | same | same | same | 25 | min |

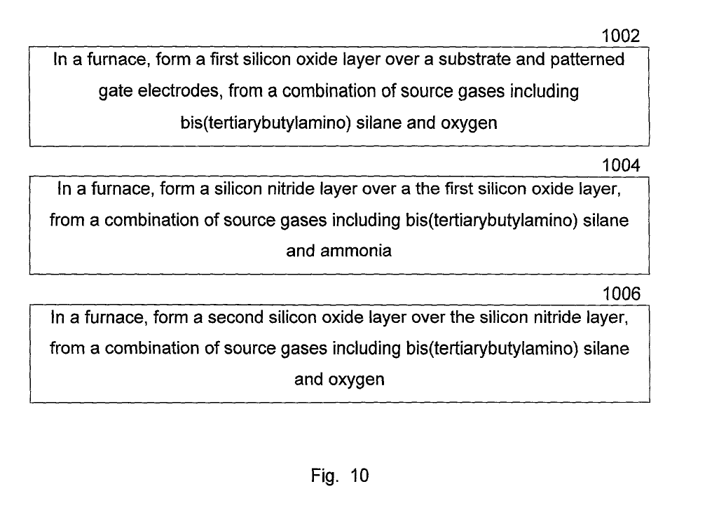

FIGS. 10-12 are flow diagrams illustrating several embodiments of the methods in accordance with the present invention.

Referring now to FIG. 10, a method of forming a tri-layer of oxide/nitride/oxide by three sequential in-situ chemical depositions by the thermal decomposition of bis(tertiarybutylamino) silane with oxygen or ammonia depending on whether an oxide or nitride is to be formed is illustrated. In a furnace, a first silicon oxide layer is formed over a substrate and patterned gate electrodes, from a combination of source gases including bis(tertiarybutylamino) silane and oxygen (1002). This is typically a vertically oriented furnace with source gases supplied from the bottom. The substrates, typically silicon wafers, may be, but are not required to be, rotated in the furnace during the deposition. After deposition of the first silicon oxide layer, the source gases are typically purged from the furnace by flowing N₂ gas therethrough. Without removing the wafers from the furnace, a silicon nitride layer is formed over a the first silicon oxide layer, from a combination of source gases including bis(tertiarybutylamino) silane and ammonia (1004). Again, the source gases are typically purged from the furnace by flowing N₂ gas therethrough. Without removing the wafers from the furnace, a second silicon oxide layer is formed over the silicon nitride layer, from a combination of source gases including bis(tertiarybutylamino) silane and oxygen (1006). Once the tri-layer structure has been formed, sidewall spacers, either conventional shaped spacers or L-shaped spacers may be formed with well known etching processes.

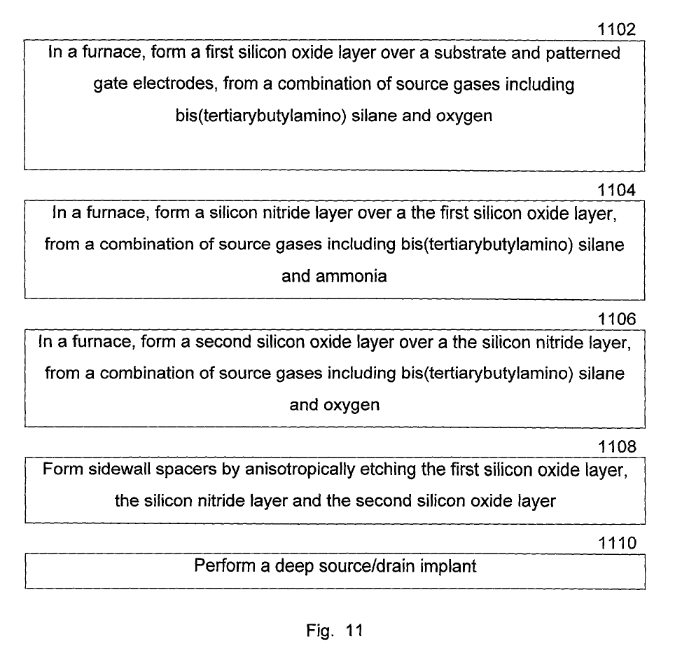

Referring now to FIG. 11, a method of forming a field effect transistor that includes the formation of a tri-layer of oxide/nitride/oxide by three sequential in- situ chemical depositions by the thermal decomposition of bis(tertiarybutylamino) silane with oxygen or ammonia depending on whether an oxide or nitride is to be formed is illustrated. In a furnace, a first silicon oxide layer is formed over a substrate and patterned gate electrodes, from a combination of source gases including bis(tertiarybutylamino) silane and oxygen (1102). After deposition of the first silicon oxide layer, the source gases are typically purged from the furnace by flowing N₂ gas therethrough. Without removing the wafers from the furnace, a silicon nitride layer is formed over a the first silicon oxide layer, from a combination of source gases including bis(tertiarybutylamino) silane and ammonia (1104). Again, the source gases are typically purged from the furnace by flowing N₂ gas therethrough. Without removing the wafers from the furnace, a second silicon oxide layer is formed over the silicon nitride layer, from a combination of source gases including bis(tertiarybutylamino) silane and oxygen (1106). Sidewall spacers are formed by anisotropically etching the first silicon oxide layer, the silicon nitride layer and the second silicon oxide layer (1108). After formation of the sidewall spacers, deep source/drain regions are formed by ion implantation (1110).

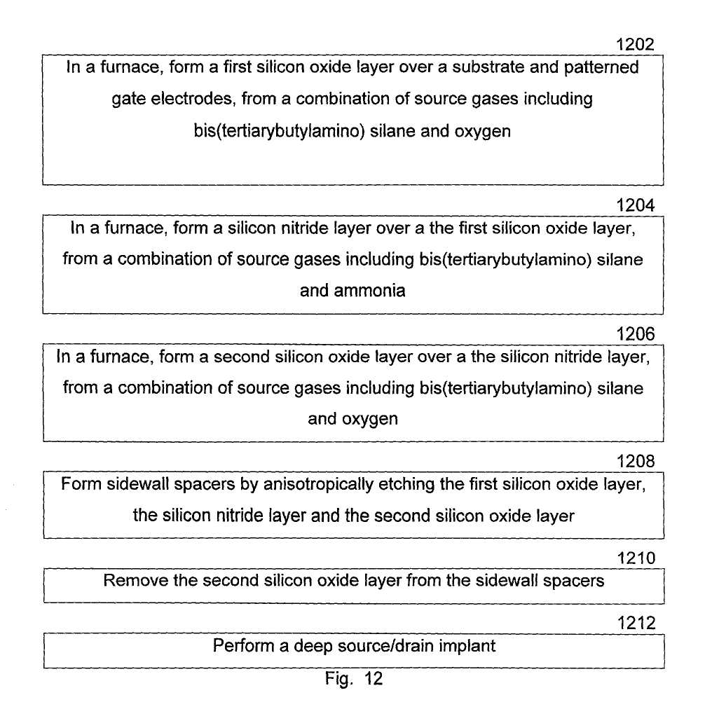

Referring now to FIG. 12, an alternative method of forming a field effect transistor that includes the formation of a tri-layer of oxide/nitride/oxide by three sequential in-situ chemical depositions by the thermal decomposition of bis(tertiarybutylamino) silane with oxygen or ammonia depending on whether an oxide or nitride is to be formed is illustrated. In a furnace, a first silicon oxide layer is formed over a substrate and patterned gate electrodes, from a combination of source gases including bis(tertiarybutylamino) silane and oxygen (1202). After deposition of the first silicon oxide layer, the source gases are typically purged from the furnace by flowing N₂ gas therethrough. Without removing the wafers from the furnace, a silicon nitride layer is formed over the first silicon oxide layer, from a combination of source gases including bis(tertiarybutylamino) silane and ammonia (1204). Again, the source gases are typically purged from the furnace by flowing N₂ gas therethrough. Without removing the wafers from the furnace, a second silicon oxide layer is formed over the silicon nitride layer, from a combination of source gases including bis(tertiarybutylamino) silane and oxygen (1206). Sidewall spacers are formed by anisotropically etching the first silicon oxide layer, the silicon nitride layer and the second silicon oxide layer (1208). After formation of the sidewall spacers, the second oxide layer is removed to form L-shaped spacers (1210). Deep source/drain regions having an improved, more gradual doping profile between the tip regions and the deep SID portion are formed by ion implantation (1212). By performing the deep SID implant with the L-shaped spacers in place, a partial penetration of the outwardly extending bottom portion of the L-shaped spacers by the ion beam takes place thereby producing a region of intermediate doping concentration and depth between the tip regions and the deep source/drain regions.

Conclusion

Embodiments of the present invention provide a sidewall spacer structure for FETs that is produced at low temperature and in a single reaction environment.

An advantage of some embodiments of the present invention is that the gap-fill capability for a dielectric layer formed over and between FETs is improved.

A further advantage of some embodiments of the present invention is that silicide encroachment over the spacer is reduced.

A still further advantage of some embodiments of the present invention is that SID series resistance is reduced.

A still further advantage of some embodiments of the present invention is the gate-edge component of the junction capacitance is reduced.

Various modifications from the specifically described structures and processes will be apparent to those skilled in the art and having the benefit of this disclosure. Accordingly, it is intended that all such modifications and alterations be considered as within the spirit and scope of the invention as defined by the subjoined claims.

What is claimed is:

1. A method of forming sidewall spacers adjacent opposing vertical sides of a gate electrode, comprising:
forming at least one gate electrode over a substrate;
forming a first silicon oxide film conformally over the substrate and gate electrode from a combination of gases including bis-(tertiarybutylamino)silane and oxygen;
forming a silicon nitride film conformally over the first silicon oxide film from a combination of gases including bis-(tertiarybutylamino)silane; and
forming a second silicon oxide film over the silicon nitride film from a combination of gases including bis-(tertiarybutylamino)silane and oxygen.

2. The method of claim 1, wherein forming the first silicon oxide film comprises providing one or more wafers in a furnace at a first temperature, and flowing BTBAS and oxygen into the furnace.

3. The method of claim 2, wherein, forming the silicon nitride film, and the second silicon oxide film comprises keeping the one or more wafers in the furnace.

4. The method of claim 2, wherein forming the silicon nitride film comprises maintaining the one or more wafers in the furnace at a second temperature, and flowing BTBAS and NH₃ into the furnace.

5. The method of claim 4, wherein forming the second oxide film comprises maintaining the one or more wafers in the furnace at the first temperature and flowing BTBAS and oxygen into the furnace.

6. The method of claim 4, wherein the first temperature is in the range of 550° C. to 580° C., and the second temperature is in the range of 580° C. to 600° C.

7. The method of claim 1, further comprising, prior to forming the film silicon nitride film and subsequent to forming the first oxide film, purging the furnace.

8. The method of claim 7, wherein purging the furnace comprises ceasing the flow of BTBAS and oxygen, and flowing N₂ into the furnace.

9. The method of claim 1, further comprising, prior to forming the second oxide film and subsequent to forming the silicon nitride film, purging the furnace.

10. The method of claim 9, wherein purging the furnace comprises ceasing the flow of BTBAS and NH₃, and flowing N₂ into the furnace.

11. A method of forming a transistor, comprising:
forming at least one gate electrode over a gate dielectric layer, the gate dielectric layer disposed on a substrate;
depositing a first silicon oxide film conformally over the substrate and gate electrode from a combination of gases comprising bis-(tertiarybutylamino)silane and oxygen;
depositing a silicon nitride film conformally over the first silicon oxide film from a combination of gases comprising bis-(tertiarybutylamino)silane and ammonia;
depositing a second silicon oxide film over the silicon nitride film from a combination of gases comprising bis-(tertiarybutylamino)silane and oxygen; and
forming a first sidewall spacer.

12. The method of claim 11, wherein the first silicon oxide, the silicon nitride, and the second silicon oxide are deposited in-situ.

13. The method of claim 11, wherein depositing the first silicon oxide, the silicon nitride, and the second silicon oxide are all done in a first furnace.

14. The method of claim 13, wherein the first furnace is vertically oriented and the BTBAS, oxygen, nitrogen, and ammonia, each flow into the furnace from a bottom of the vertically oriented furnace.

15. The method of claim 11, further comprising implanting dopants to form a of deep source/drain region in the substrate adjacent at least two opposing sides of the gate electrode.

16. The method of claim 14, wherein forming a first sidewall spacer comprises anisotropically etching the second silicon oxide layer, the silicon nitride layer, and the first silicon oxide layer.

17. The method of claim 16, further comprising removing the second oxide layer so as to form L-shaped spacers.

18. The method of claim 17, further comprising implanting dopants to form a deep source/drain region in the substrate, adjacent to each opposing side of the L-shaped spacers.

19. The method of claim 17, wherein implanting dopants includes a partial passage of ions from an ion beam through a portion of the L-shaped spacers.

20. A field effect transistor, comprising:
a gate electrode overlying a gate dielectric layer disposed on a substrate;
a pair of L-shaped spacers adjacent opposing vertical sidewalls of the gate electrode; and
a pair of source/drain regions disposed in the substrate and aligned, respectively, adjacent to the pair of L-shaped spacers;
wherein each of the source/drain regions has a shallow tip portion underlying each L-shaped spacer, a deep portion spaced away from the L-shaped spacer, and an intermediate portion having a depth greater than that of the shallow tip portion and less than that of the deep portion.

21. The field effect transistor of claim 20, wherein each L-shaped spacer comprises a silicon oxide layer immediately adjacent to the gate electrode.

22. The field effect transistor of claim 21, wherein each L-shaped spacer comprises a silicon nitride layer adjacent to the silicon oxide layer.

23. The field effect transistor of claim 22, wherein the silicon nitride layer is thicker than the silicon oxide layer.
